(19) United States
(12) Patent Application Publication
(10) Pub. No.: US 2008/0218969 A1
(43) Pub. Date: Sep. 11, 2008

(54) ELECTRONIC SYSTEM WITH ADJUSTABLE VENTING SYSTEM

(75) Inventor: Yosuke Muraki, Campbell, CA (US)

Correspondence Address: LAW OFFICES OF MIKIO ISHIMARU, 333 W. EL CAMINO REAL, SUITE 330, SUNNYVALE, CA, 94087, US

(73) Assignees: SONY CORPORATION, Tokyo (JP); SONY ELECTRONICS INC., Park Ridge, NJ (US)

(21) Appl. No.: 11/684,591

(22) Filed: Mar. 9, 2007

(51) Int. Cl. H05K 7/20

(52) U.S. Cl. 361/695; 361/688

(57) ABSTRACT

An electronic system is provided including determining temperature in an enclosure, controlling airflow into the enclosure based on the temperature, and adjusting the airflow through an opening of the enclosure.

### TECHNICAL FIELD

The present invention relates generally to electronic systems and more particularly to electronic systems having vents.

### BACKGROUND ART

Modern consumer electronics, such as game consoles, notebook computers, smart phones, personal digital assistants, and location based services devices, as well as enterprise class electronics, such as servers, storage arrays, and routers, are packing more integrated circuits into an ever shrinking physical space with expectations for decreasing cost. Contemporary electronics expose integrated circuits to more demanding and sometimes new environmental conditions, such as cold, heat, and humidity requiring the overall system to provide robust thermal management solutions. Higher performance, more functions, lower power usage, and longer usage off battery power are yet other expectations upon contemporary electronics.

As more functions are packed into the integrated circuits, more integrated circuits into the package, and more integrated circuits into electronic systems, more heat is generated degrading the performance, the reliability, and the life time of the integrated circuits as well as the overall system. Numerous technologies have been developed to meet these requirements. Some of the research and development strategies focus on the system power supplies, ventilation, and enclosure fans while others focus on the integrated circuit technologies and associated integrated circuit packaging. Other focus on other forms of thermal management solutions, such as heat sinks/slug, heat spreaders, or localized fans directly over the integrated circuit. Yet other solutions may use a combination of solutions.

More specifically, enclosure fans are often used to evacuate warm air from enclosures in which electronic systems are contained. For example, most computer systems include one or more cooling enclosure fans to aid circulating air inside the enclosures and for maintaining the temperature inside the enclosures within an acceptable range. The increased airflow provided by the enclosure fans typically aids in eliminating heat that may otherwise build up and adversely affect system operation. Employing enclosure fans is especially helpful in ensuring proper operation for certain integrated circuits, such as central processing units (CPUs), with relatively high operating temperatures.

A seemingly natural part of fan operation is the ventilation or the baffle system that cooperate with the fans. Typically, current electronic systems have vents or openings in the chassis of the electronic system for airflow intake and exhaust. These vents or openings remain open and may include other items as air filter to mitigate or eliminate contamination entering the electronic system with the airflow. The air filter is most effective with the fans, enclosure fans or localized fans, directing the airflow through the filter.

Also, the manufacture, shipment, and storage of the electronic system provide numerous opportunities for contamination of the electronic system that may result in yield decrease, intermittent or permanent functional failures, and increased cost. For example, as the electronic system is manufactured, care is taken not to contaminate the internals in the electronic system. Manufacturing environments typically are well controlled to maximize the manufacturing yield.

From manufacturing to shipping, to storing, and to having the electronic system at the end customer site, the electronic systems are exposed to everyday environments that are typically not as well controlled as a manufacturing site. For example, an electronic system, such as computer system, may be sitting on a floor at a customer's house. Normal accumulation of dust and other contamination may clog or reduce the airflow. Also, some of the contamination may be conductive that may short out electrical components in the electronic system. Other contaminants may be flammable potentially causing fires as the electronic system heats up.

On the other hand, the inability to remove excessive heat from electronic systems may lead to permanent damage of the system as well as the integrated circuits. The economic impacts may be best illustrated in the following example. As a product goes through various life cycle phases, such as design, design testing, manufacturing pilot runs, production test, and final production, the cost increases by an order of magnitude from one phase to the next phase of the life cycle when a change is required to a major electronic component of the electronic system.

Designing cooling solutions for systems is also a time-consuming process for the thermal design engineer. Typically, a controller card has to be designed and tested for controlling the fan speed and other functionality, such as failure detection and alarm settings. Multiple control cards are tested to obtain the right combination of fans, fan speeds, alarm settings, etc. Multiple iterations of installing sample fans in a system, determining the adequate fan speeds and power required, and testing the fans in the system, for example, are costly and inefficient.

Thus, a need still remains for an electronic system with a dynamic thermal management solution providing lower power consumption, longer battery life operation, lower cost manufacturing, improved yield, and higher reliability for the electronic systems. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an electronic system including determining temperature in an enclosure, controlling airflow into the enclosure based on the temperature, and adjusting the airflow through an opening of the enclosure.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIGS. 1A, 1B, and 1C are schematic views of examples of electronics systems in embodiments of the present invention;

FIG. 2 is an isometric view of an electronic system in an embodiment of the present invention;

FIG. 3 is the structure of FIG. 2 with the first flaps and the second flaps in an opened position;

FIG. 4 is a cutout view of the electronic system of FIG. 3;

FIG. 5 is a tabulated view of a table for the positions of the first flaps of FIG. 4 under a number of conditions;

FIG. 6 is a cutout view of an electronic system in an alternative embodiment of the present invention; and

FIG. 7 is a flow chart of an electronic system for operation of the electronic system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGS. In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “system” as used herein means and refers to the method and to the apparatus of the present invention in accordance with the context in which the term is used.

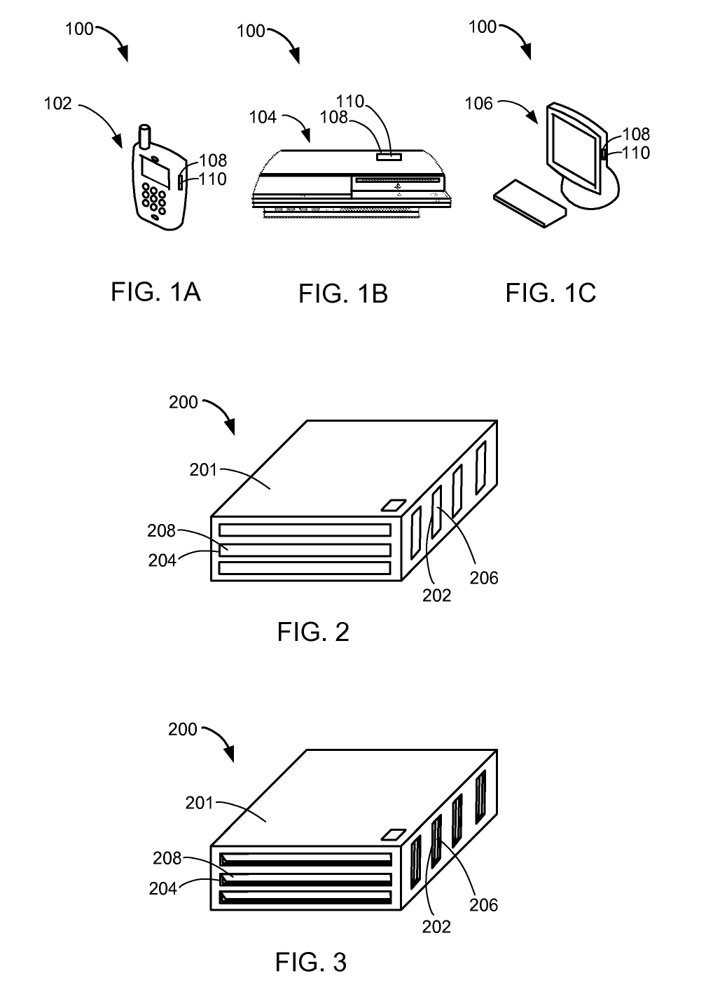

Referring now to FIGS. 1A, 1B, and 1C, therein are shown schematic views of examples of electronics systems 100 in embodiments of the present invention. A smart phone 102, a game console 104, and a computer system 106 are examples of the electronic systems using the present invention. The electronic systems 100 may be any system that performs any function for the creation, transportation, storage, and consumption of information. For example, the smart phone 102 may create information by transmitting voice to the computer system 106 or consume information by playing a game with the game console 104. The smart phone 102, the game console 104, and the computer system 106 may be used to store the information. Other electronic systems (not shown) may be used to transport information amongst the smart phone 102, the game console 104, and the computer system 106.

The smart phone 102, the game console 104, and the computer system 106 each has openings 108 and flaps 110 for airflow. For illustrative purposes, the openings 108 and the flaps 110 are shown substantially the same between the smart phone 102, the game console 104, and the computer system 106. Although it is understood that the openings 108 and the flaps 110 between the smart phone 102, the game console 104, and the computer system 106 may be different, such as different form factor or different sizes.

Referring now to FIG. 2, therein is shown an isometric view of an electronic system 200 in an embodiment of the present invention. The electronic system 200 represents any one of the electronic systems 100 of FIG. 1.

The isometric view depicts the electronic system 200 includes an enclosure 201 having first openings 202 and second openings 204. The first openings 202 may be preferably obstructed by first flaps 206 in a closed position. The second openings 204 may be preferably obstructed by second flaps 208.

The first flaps 206 and the second flaps 208 may be in the closed position with the electronic system 200 in a number of different states. For example, the electronic system 200 may be in a powered off state. The first flaps 206 and the second flaps 208 in the closed position provide protection from contamination entering the electronic system 200. The closed position of the first flaps 206 and the second flaps 208 may also provide an aesthetic view of the electronic system 200 for marketing or for displaying.

Another example, the electronic system 200 may preferably be in a powered on stated in environments that may be cooler than a lower bound of the operating specification of the electronic system 200. In this example, the electronic system 200 may position the first flaps 206 and the second flaps 208 between an opened position and the closed position. This alternating closed and opened position allows the electronic system 200 from being cooled below the lower bound of the operating range while preventing overheating.

Referring now to FIG. 3, therein is shown the structure of FIG. 2 with the first flaps 206 and the second flaps 208 in an opened position. The electronic system 200 is shown in a powered on state. The first flaps 206 and the second flaps 208 are shown in the opened position preferably allowing for airflow through the first openings 202 and the second openings 204 of the enclosure 201.

The first flaps 206 and the second flaps 208 may remain in the opened position with the electronic system 200 in the powered down state. For example, the electronic system 200 may experience an increase in temperature after power down. The heat generated by the electronic system 200 may be trapped inside the electronic system 200 if the first flaps 206 and the second flaps 208 placed in the closed position without allowing the generated heat to escape. The ambient may be warm enough to continue to heat the electronic system 200 potentially causing damage.

The first flaps 206 and the second flaps 208 may be moved or adjusted to the closed position with the electronic system 200 in the powered off state by a timed or memory mechanism (not shown). The timed or memory mechanism may be electrical in nature, mechanical in nature, or a combination thereof.

For example, charge may be stored on a capacitor (not shown) providing a timed and memory mechanism by holding the first flaps 206 and the second flaps 208 in the opened position. As the charge in the capacitor decays, the first flaps 206 and the second flaps 208 may move to the closed position.

Another example, a mechanical opener (not shown) may provide material expansion based on coefficient of thermal expansion (CTE). The mechanical opener may be used to hold the first flaps 206 and the second flaps 208 in the opened position with the temperature of the electronic system 200 above a predetermined temperature threshold or in a predetermined temperature range. As the electronic system 200 cools, the mechanical opener may preferably contract resulting in closing the first openings 202 and the second openings 204 with the first flaps 206 and the second flaps 208, respectively.

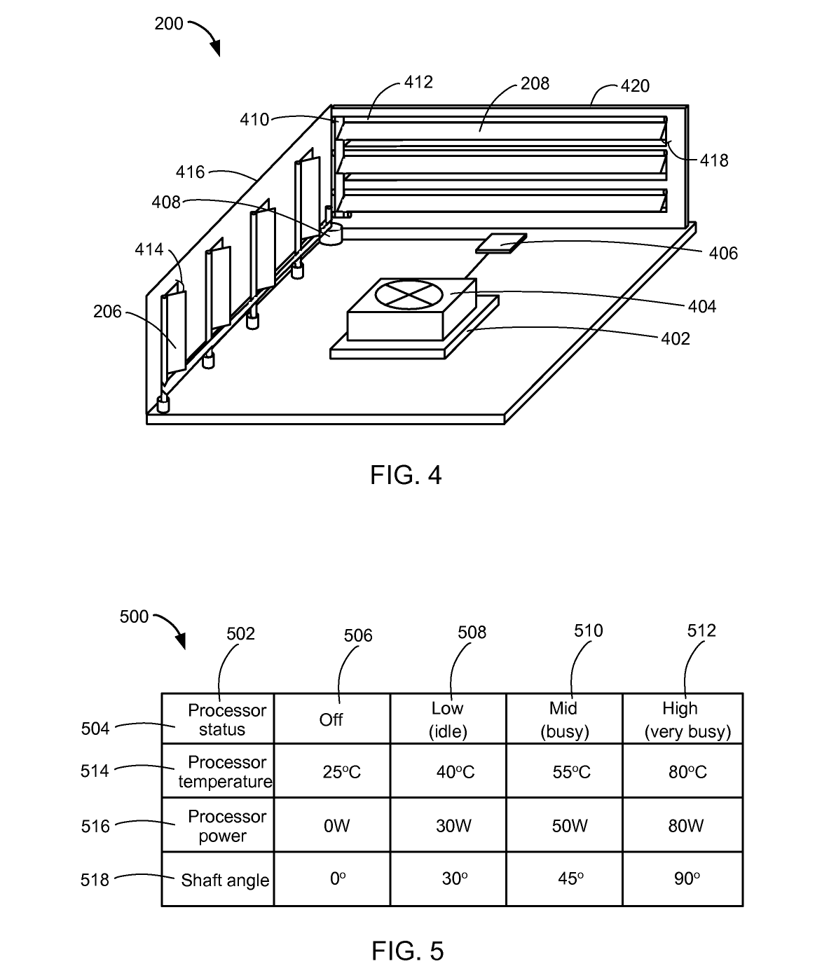

Referring now to FIG. 4, therein is shown is a cutout view of the electronic system 200 of FIG. 3. The cutout view depicts the first flaps 206 and the second flaps 208 in the opened position. The cutout view also depicts the electronic system 200 having a computing integrated circuit device 402, such as a processor, having a fan 404 thereover. The computing integrated circuit device 402, the fan 404, or a combination thereof connects with a flap control device 406, such as an actuator computing integrated circuit device. The flap control device 406 connects with an actuator 408, such as a motor, for opening or closing the first flaps 206 and the second flaps 208. The computing integrated circuit device 402, the flap control device 406, or a combination thereof may also control the fan 404.

For illustrative purposes, the computing integrated circuit device 402 and the flap control device 406 are shown as distinct integrated circuit devices, although it is understood that the functions of the computing integrated circuit device 402 and the flap control device 406 may in be in distinct devices, such as in a single integrated circuit device or partitioned between different integrated circuit devices.

The actuator 408 preferably connects with positioning mechanisms 410, such as belts or rods. The positioning mechanisms 410 connect with flap movement mechanisms 412, such as shafts or rods. The flap movement mechanisms 412 connect with the first flaps 206 and the second flaps 208.

For illustrative purposes, the actuator 408 is shown connected with both the first flaps 206 and the second flaps 208, although it is understood that the first flaps 206 and the second flaps 208 may be controlled separately. Also for illustrative purposes, the positioning mechanisms 410 are shown substantially the same type for the first flaps 206 and the second flaps 208, although it is understood that the first flaps 206 and the second flaps 208 may not have substantially the same type of the positioning mechanisms 410.

Further for illustrative purposes, the flap movement mechanisms 412 are shown substantially the same type for the first flaps 206 and the second flaps 208, although it is understood that the first flaps 206 and the second flaps 208 may not have substantially the same type of the flap movement mechanisms 412. Yet further for illustrative purposes, the first flaps 206 and the second flaps 208 are shown substantially the same type, although it is understood that the first flaps 206 and the second flaps 208 may not be substantially the same type.

The electronic system 200 may control the first flaps 206 and the second flaps 208 in a number of different ways. For example, the computing integrated circuit device 402 may include a thermostat (not shown) monitoring a temperature of the computing integrated circuit device 402, the surrounding area of the computing integrated circuit device 402, or a combination thereof. The computing integrated circuit device 402 communicates with the flap control device 406 providing a number of information such as temperature of the computing integrated circuit device 402. The flap control device 406 may also provide information to the computing integrated circuit device 402 providing communication feedback for a closed loop system.

The computing integrated circuit device 402 may communicate a current temperature, such as 60 degrees centigrade, to the flap control device 406. The flap control device 406 controls the actuator 408 based on the current temperature from the computing integrated circuit device 402. The actuator 408 preferably moves the first flaps 206 to a first angle 414 measured from a first wall 416 of the electronic system 200. The actuator 408 also preferably moves the second flaps 208 to a second angle 418 measured from a second wall 420 of the electronic system 200. The first wall 416 and the second wall 420 are part of the enclosure 201 of FIG. 1.

The actuator 408 moves or adjusts the first flaps 206 and the second flaps 208 to the first angle 414 and the second angle 418, respectively, by controlling the positioning mechanisms 410 to the flap movement mechanisms 412. The flap movement mechanisms 412 connected to the first flaps 206 position the first flaps 206 to the first angle 414. The flap movement mechanisms 412 connected to the second flaps 208 position the second flaps 208 to the second angle 418.

The movement control and mechanical relationships from the computing integrated circuit device 402 to the flap control device 406 through the flap movement mechanisms 412 attached to the first flaps 206 and to the second flaps 208 control the positioning, such as the opened position or the closed position, of the first flaps 206 and the second flaps 208. These relationships also control the first angle 414 and the second angle 418.

Referring now to FIG. 5, therein is shown a tabulated view of a table 500 for the positions of the first flaps 206 of FIG. 4 under a number of conditions. The table 500 or a similar table (not shown) may also represent the positions of the second flaps 208 of FIG. 4. The table 500 depicts an example of the relationship from the computing integrated circuit device 402 of FIG. 4 with the first angle 414 of FIG. 4.

A first column 502 of the table 500 depicts row headings. A first row 504 provides a status of the computing integrated circuit device 402. In this example, the computing integrated circuit device 402 is preferably a processor. A second column 506 of the first row 504 depicts the processor status in an off state. A third column 508 of the first row 504 depicts the processor status in low activity state or in an idle state. A fourth column 510 of the first row 504 depicts that processor status in a medium activity state or a busy state. A fifth column 512 of the first row 504 depicts that processor status in a high activity state or a very busy state.

A second row 514 of the table 500 depicts temperature samples of the computing integrated circuit device 402 in the activity states described in the above paragraph. The second column 506 of the second row 514 has the temperature of the computing integrated circuit device 402 as 25 degrees centigrade. The third column 508 of the second row 514 has the temperature of the computing integrated circuit device 402 as 40 degrees centigrade. The fourth column 510 of the second row 514 has the temperature of the computing integrated circuit device 402 as 55 degrees centigrade. The fifth column 512 of the second row 514 has the temperature of the computing integrated circuit device 402 as 80 degrees centigrade.

A third row 516 of the table 500 depicts the power consumption of the computing integrated circuit device 402 with the activity states described in the above. The second column 506 of the third row 516 has the power consumption of the computing integrated circuit device 402 as 0 Watts. The third column 508 of the third row 516 has the power consumption of the computing integrated circuit device 402 as 30 Watts. The fourth column 510 of the third row 516 has the power consumption of the computing integrated circuit device 402 as 50 Watts. The fifth column 512 of the third row 516 has the power consumption of the computing integrated circuit device 402 as 80 Watts.

A fourth row 518 of the table 500 depicts the first angle 414 of the first flaps 206 with the activity states described above. The second column 506 of the fourth row 518 has the first angle 414 of the first flaps 206 as 0 degrees. The third column 508 of the fourth row 518 has the first angle 414 of the first flaps 206 as 30 degrees. The fourth column 510 of the fourth row 518 has the first angle 414 of the first flaps 206 as 45 degrees. The fifth column 512 of the fourth row 518 has the first angle 414 of the first flaps 206 as 90 degrees.

The table 500 generally depicts an example that as the activity level of the computing integrated circuit device 402 increases, the temperature communicated to the flap control device 406 of FIG. 4 is higher. The higher temperature reflects an increased power consumption of the computing integrated circuit device 402. As the activity level of the computing integrated circuit device 402 increases, the first angle 414 for the first flaps 206 are increased to increase the airflow through the electronic system 200 of FIG. 4.

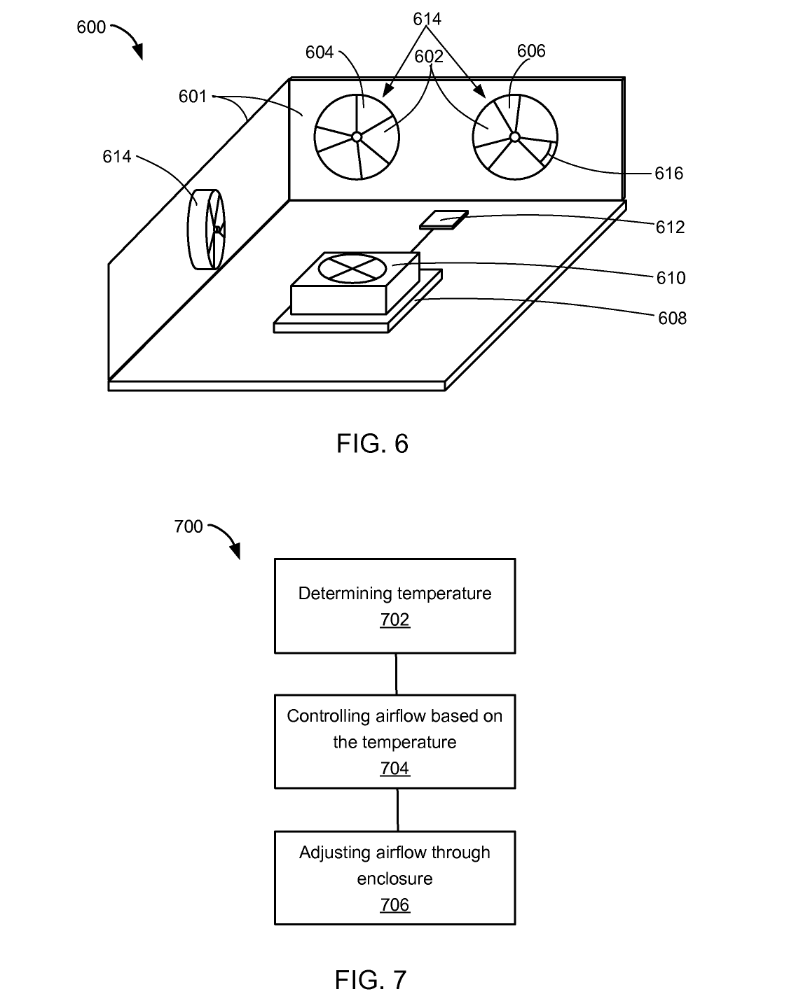

Referring now to FIG. 6, therein is shown a cutout view of an electronic system 600 in an alternative embodiment of the present invention. The cutout view depicts first flaps 602 and second flaps 604. The first flaps 602 rotate with the second flaps 604 are fixed. As the first flaps 602 rotate, openings 606 may be exposed at areas not covered by both the first flaps 602 and the second flaps 604.

The cutout view also depicts the electronic system 600 having a computing integrated circuit device 608, such as a processor, having a fan 610 thereover. The computing integrated circuit device 608, the fan 610, or a combination thereof preferably connect with a flap control device 612, such as an actuator computing integrated circuit device. The flap control device 612 preferably connects with actuating flaps 614 having the first flaps 602 and the second flaps 604.

The actuating flaps 614 preferably rotate the first flaps 602 across the second flaps 604 such that the areas not covered by both the first flaps 602 and the second flaps 604 provide the openings 606 in an enclosure 601 of the electronic system 600. As the non-covered areas increase, sizes or areas of the openings 606 for the electronic system 600 also increase. The actuating flaps 614 preferably includes an actuating mechanism (not shown), such as an actuator.

The electronic system 600 may control and adjust the first flaps 602 and the second flaps 604 in a number of different ways. For example, the computing integrated circuit device 608 may include or connect with a thermostat (not shown) for monitoring a temperature of the computing integrated circuit device 608, the surrounding area of the computing integrated circuit device 608, the enclosure 601, or a combination thereof. The computing integrated circuit device 608 communicates with the flap control device 612 providing a number of information such as temperature of the computing integrated circuit device 608. The flap control device 612 may also provide information to the computing integrated circuit device 608 providing communication feedback for a closed loop system.

The computing integrated circuit device 608 may communicate a current temperature, such as 60 degrees centigrade, to the flap control device 612. The flap control device 612 controls the actuating flaps 614 based on the current temperature from the computing integrated circuit device 608. The actuating flaps 614 preferably rotate the first flaps 602 to a first angle 616 measured from the second flaps 604.

The movement control and mechanical relationships from the computing integrated circuit device 608 to the flap control device 612 through the actuating flaps 614 control the positioning, such as the opened position or the closed position, of the first flaps 602 and the sizes of the openings 606. These relationships also control the first angle 616.

Referring now to FIG. 7, therein is shown a flow chart of an electronic system 700 for operation of the electronic systems 100 in an embodiment of the present invention. The system 700 includes determining temperature in an enclosure in a block 702; controlling airflow into the enclosure based on the temperature in a block 704; and adjusting the airflow through an opening of the enclosure in a block 706.

Yet other important aspects of the embodiments include that it valuably supports and services the historical trend of reducing costs, simplifying systems, and increasing performance.

These and other valuable aspects of the embodiments consequently further the state of the technology to at least the next level.

Thus, it has been discovered that the electronic system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing stackable integrated circuit package system.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

1. A portable electronic system comprising:
determining temperature at a computing integrated circuit device in an enclosure of the portable electronic system;
controlling airflow into the enclosure based on the temperature; and
adjusting the airflow through an opening of the enclosure.

2. (canceled)

3. The system as claimed in claim 1 wherein controlling the airflow into the enclosure based on the temperature includes controlling the airflow into the enclosure with the computing integrated circuit device in the enclosure.

4. The system as claimed in claim 1 wherein adjusting the airflow through the opening of the enclosure with the computing integrated circuit device includes closing the opening.

5. The system as claimed in claim 1 wherein adjusting the airflow through the opening of the enclosure includes adjusting a flap adjacent to the opening.

6. A portable electronic system comprising:
capturing temperature a computing integrated circuit device in an enclosure of the portable electronic system;
controlling airflow into the enclosure based on the temperature;
adjusting the airflow through an opening of the enclosure with the computing integrated circuit device; and
adjusting the temperature in the enclosure with the airflow.

7. The system as claimed in claim 6 further comprising operating a fan in the enclosure.

8. The system as claimed in claim 6 wherein adjusting the airflow through the opening of the enclosure with the computing integrated circuit device includes controlling an angle of a flap to the opening.

9. The system as claimed in claim 6 wherein adjusting the airflow through the opening of the enclosure with the computing integrated circuit device includes operating an actuator.

10. The system as claimed in claim 6 wherein adjusting the airflow through the opening of the enclosure with the computing integrated circuit device includes operating a positioning mechanism.

11. A portable electronic system comprising:
an enclosure of the portable electronic system having an opening;
a first flap adjacent to the opening; and
a computing integrated circuit device for determining temperature thereat in the enclosure for controlling the first flap.

12. The system as claimed in claim 11 wherein the computing integrated circuit device for controlling the first flap is based on the computing integrated circuit device having a temperature from within the enclosure.

13. The system as claimed in claim 11 further comprising a second flap with the opening exposed from an area not covered by the first flap and the second flap.

14. The system as claimed in claim 11 wherein the first flap is in a closed position.

15. The system as claimed in claim 11 wherein the computing integrated circuit device for controlling the first flap includes the first flap at an angle from the opening.

16. The system as claimed in claim 11 wherein the first flap at a position for adjusting airflow into the enclosure.

17. The system as claimed in claim 16 further comprising a fan in the enclosure.

18. The system as claimed in claim 16 further comprising a positioning mechanism coupled with the first flap.

19. The system as claimed in claim 16 further comprising a flap control device coupled with the computing integrated circuit device.

20. The system as claimed in claim 16 further comprising an actuator for moving the first flap.
